(19) United States
(12) Patent Application Publication
(10) Pub. No.: US 2026/0261259 A1
(43) Pub. Date: Sep. 3, 2026

(54) CLAMP CONTROL OF SWITCH CIRCUITRY

(71) Applicant: Infineon Technologies Austria AG, Villach (AT)

(72) Inventor: Kennith Kin LEONG, Villach (AT)

(21) Appl. No.: 19/068,428

(22) Filed: Mar. 3, 2025

(51) Int. Cl. H03K 17/0812

(52) U.S. Cl. CPC H03K 17/08122

(57) ABSTRACT

An apparatus may include a switch such as a bidirectional switch and first clamp circuitry. The bidirectional switch may include a first terminal and a second terminal to receive control input. The control input is operative to control flow of current through the bidirectional switch between a third terminal and a fourth terminal of the bidirectional switch. The first clamp circuitry may be directly coupled between the fourth terminal and the first terminal, where the first clamp circuitry controls a voltage at the first terminal. The apparatus may further include second clamp circuitry such as directly coupled between the third terminal and the second terminal. The second clamp circuitry can be configured to control a voltage at the second terminal. The first clamp circuitry and the second clamp circuitry may prevent undesirable turn on of the bidirectional switch during certain operating conditions.

### BACKGROUND

Conventional switch circuitry such as unidirectional or bidirectional field effect transistor can be used to control conveyance of current.

A conventional unidirectional field effect transistor includes a gate node and a source node. A gate-to-source voltage between the gate node and the source node controls flow of current through the unidirectional field effect transistor.

Another type of conventional field effect transistor is a so-called HEMT device, which is a type of transistor that uses semiconductor materials with high electron mobility, allowing for high-speed switching (high-frequency operation). In general, a high-electron-mobility transistor (HEMT or HEM FET), is a field-effect transistor incorporating a junction between two materials with different band gaps (i.e. a heterojunction) as the channel instead of a doped region (as is generally the case for a MOSFET).

A conventional bidirectional field effect transistor (BiDFET) is a unique switch component supporting conveyance of current in multiple directions. The conventional bidirectional field effect transistor may include multiple gate notes and multiple source nodes. A gate-to-source voltage between a first gate node and a first source node of the bidirectional field effect transistor controls flow of current in one direction while the gate-to-source voltage between a second gate node and a second source node of the bidirectional field effect transistor controls flow of current in a second direction through the bidirectional field effect transistor.

### BRIEF DESCRIPTION

This disclosure includes the observation that a field effect transistor may experience false or improper activation during certain environmental conditions such as transient or surge voltage events. Such a condition of false or improper activation may occur when the gate driver configured to drive the one or more gate nodes of the field effect transistor is not powered (driven) and a typical active gate shorting is not active. During the transient voltage or surge event, the gate to gate capacitance of the switch may be sufficiently charged, resulting in improper activation of the switch.

Techniques herein prevent undesirable activation of a switch during transient voltage events.

For example, a first apparatus as discussed herein can be configured to include a bidirectional switch and al first clamp circuitry. The bidirectional switch may include a first terminal and a second terminal to receive control input. When present, the control input may control (such as prevent, adjust, etc.) flow of current through the bidirectional switch between a third terminal and a fourth terminal of the bidirectional switch. The first clamp circuitry may be directly coupled between the fourth terminal and the first terminal, where the first clamp circuitry controls a voltage at the first terminal such as in the absence of the control input. The apparatus may further include second clamp circuitry such as directly coupled between the third terminal and the second terminal. The second clamp circuitry can be configured to control a voltage at the second terminal.

The first clamp circuitry and the second clamp circuitry may prevent undesirable turn on of the bidirectional switch between the third terminal and the fourth terminal during first operating conditions. Conversely, during second operating conditions, the first clamp circuitry may be operated in an off state while driver circuitry controls operation of the bidirectional switch.

Note that the combination of the bidirectional switch, the first clamp circuitry, and the second clamp circuitry may be integrally fabricated in a single semiconductor chip component. Alternatively, the first clamp circuitry can be implemented in a first semiconductor chip component while the bidirectional switch is implemented in a second semiconductor chip component.

In still further examples, the bidirectional switch as discussed herein may be implemented as a bidirectional field effect transistor. The first terminal as previously discussed may be a first gate node of the bidirectional switch. The second terminal as previously discussed may be a second gate node of the bidirectional switch.

Yet further, note that the third terminal may be a first source node of the bidirectional switch, where the first source node may be associated with the first gate node of the bidirectional switch; and the fourth terminal may be a second source node of the bidirectional switch, where the second source node may be associated with the second gate node of the bidirectional switch.

In still other examples, the first apparatus can be configured to include second clamp circuitry directly coupled between the second gate node and the first source node, where the second clamp circuitry can be configured to control a voltage applied to the second gate node.

Note further that the first clamp circuitry may include a first capacitor component configured to provide first capacitive coupling of first energy received from the second source node, where the first energy may control a magnitude of the voltage at the first gate node with respect to a voltage at the first source node.

Yet further, note that the first clamp circuitry as discussed herein may include a first circuit path, where the first circuit path can be configured to extend between the first terminal and the fourth terminal, and where the first circuit path may include a first capacitor component and a first switch disposed in series.

In a further example, the bidirectional switch may be a first bidirectional switch; the first capacitor component may be implemented as a second bidirectional switch.

Still further, a first output node of a first switch of the first clamp circuitry may be directly connected to the third terminal; a second output node of the first switch may be directly connected to the first terminal; and the first capacitor component may supply a control voltage to an input node (such as gate node) of the first switch, where the control voltage to the input node and corresponding first switch is configured to control a resistance provided by the first switch between the first terminal and the third terminal.

Yet further, the first switch can be configured to operate in a normally OFF-state prior to reception of the control voltage or current (first energy or charge) conveyed via the first capacitor component; the first switch can be configured to operate in an ON-state during a condition in which the control voltage is above a threshold level.

The first apparatus may further include second clamp circuitry including a second clamping switch connected between the second terminal such as second gate node and the fourth terminal such as a first source node; where a resistance of the second clamping switch between the second terminal and the fourth terminal may be controlled based on a voltage at the third terminal such as a first source node of the bidirectional switch.

No further that a magnitude of the first resistance may be operative to decrease in response a condition in which a magnitude of voltage of the third terminal temporarily surges above a threshold level.

As previously discussed, any of the switches as discussed herein may be a bidirectional GaN (Gallium Nitride) field effect transistor.

As further discussed herein, an apparatus can be configured to include: a bidirectional switch including a first gate terminal, a first source terminal, a second gate terminal, and a second source terminal; and first switch circuitry coupled between the first gate terminal and the first source terminal, the first switch circuitry operative to control a voltage of the first gate terminal based on a magnitude of a voltage at the second source terminal.

The apparatus may further include second switch circuitry coupled between the second gate terminal and the second source terminal, the second switch circuitry operative to control a voltage at the second gate terminal based on a magnitude of a voltage at the first source terminal. It is noted that the combination of the bidirectional switch, the first switch circuitry, and the second switch circuitry may be integrally fabricated in a single monolithic semiconductor chip.

As previously discussed, the bidirectional switch may be a GaN (Gallium Nitrite) bidirectional field effect transistor or any other suitable type of switch.

Yet further, it is noted that the apparatus as discussed herein can be configured to include a first capacitor component operative to provide first capacitive coupling between the second source node and a control input of the first switch circuitry, the first capacitor component operative to convey first energy from the second source terminal to the first switch circuitry. The first capacitor component may be operative to convey the first energy from the second source terminal to the first switch circuitry in response to a transient change in a magnitude of the voltage at the second source terminal. In one example, the first energy temporarily activates the first switch circuitry to an ON-state to protect the bidirectional switch from being damaged due to excessive current flow.

Still further, it is noted that a resistance provided by the first switch circuitry between the first gate terminal and the first source terminal depends on energy conveyed from the second source terminal to the first switch circuitry during a transient change in the magnitude of the voltage at the second terminal.

In accordance with further examples, the apparatus can be configured to include a first circuit path extending between the second source terminal and the first switch circuitry, where the first circuit path may include a first capacitor component, and where the first circuit path is operative to control an operational state of the first switch circuitry. Still further, it is noted that the bidirectional switch may be a first bidirectional switch; the first capacitor component may be implemented via second switch circuitry, such as where the second switch circuitry is a bidirectional switch.

In further examples, the voltage at the second source terminal may be a transient voltage. The apparatus may further include a first circuit path extending between the second source terminal and an input node of the first switch circuitry. Yet further, a first output node of the first switch circuitry may be directly connected to the first source terminal; a second output node of the first switch circuitry may be directly connected to the first source terminal; the first switch circuitry may be configured to operate in a normally OFF-state prior to reception of an input control signal applied to the input node; and the first switch circuitry may be configured to operate in an ON-state during a condition in which the magnitude of the voltage at the second source terminal is above a threshold level.

In another example, the first switch circuitry may be activated to an ON-state during a condition in which the magnitude of the voltage at the second source terminal temporarily surges above a threshold level.

In yet another example, a first resistance of the first switch circuitry between the first gate terminal and the first source terminal may be operative to decrease during a transient increase in the magnitude of the voltage of the second source terminal.

Further examples as discussed herein include a method of controlling a bidirectional switch including a first gate terminal and a second gate terminal, where the first gate terminal and the second gate terminal are operative to control (such as prevent, adjust, reduce, etc.) a magnitude of a flow of current between a first source terminal and a second source terminal of the bidirectional switch. The method may further include receiving a voltage or charge from the second source terminal of the bidirectional switch; and based on the voltage or charge received from the second source terminal, controlling a first resistance between the first gate terminal and the first source terminal. As discussed herein, the controlled first resistance and control of the first gate terminal and corresponding voltage controls operation of the bidirectional switch such that it does not turn on during certain conditions.

Note further that a second apparatus as discussed herein can be configured to include a first clamping switch coupled between a first gate terminal and a first source terminal of a main switch (bidirectional switch, unidirectional switch, etc.). The first clamping switch can be configured to prevent or reduce flow of current through the main switch between a third terminal of the main switch (such as a second source terminal or other node of the switch) and the fourth terminal of the main switch (such as a first source terminal or other node of the switch). The first clamping switch can be configured to control a first resistance between the first gate terminal and the first source terminal of the main switch based on a voltage at the second source terminal. Control of the first resistance may include reducing the first resistance such that a gate-to-source voltage between the first gate terminal and the first source terminal of the main switch is less than a respective turn on threshold level. In such an instance, when the main switch is exposed to a transient voltage condition, the first resistance and corresponding gate-to-source voltage between the first gate node and the first source node is decreased to prevent the switch from being activated to an ON-state due to the transient voltage condition.

As previously discussed, the main switch as discussed herein may be a bidirectional switch. The second apparatus as discussed herein may further include a second clamping switch coupled between a second gate terminal of the bidirectional switch and the second source terminal of the bidirectional switch. The second clamping switch can be configured to prevent or adjust the magnitude of a flow of current through the bidirectional switch between the first source terminal and the second source terminal of the bidirectional switch. The second clamping switch can be configured to control a second resistance between the second gate terminal and the second source terminal of the bidirectional switch based on a voltage at the first source terminal.

The second apparatus as discussed herein may further include: a first capacitive circuit component operative to convey first energy (charge, voltage, etc.) supplied from the second source terminal to an input node of the first clamping switch, the conveyed first energy being operative to control a magnitude of the first resistance; and a second capacitive circuit component operative to convey second energy (charge, voltage, etc.) supplied from the first source terminal to an input node of the second clamping switch, the conveyed second energy being operative to control a magnitude of the second resistance.

Yet further, the second apparatus as discussed herein can be configured to include: a first resistor including a first node and a second node, the first node of the first resistor directly connected to the input node (gate node) of the first clamping switch, where the second node of the first resistor may be directly connected to the first source node of the bidirectional switch; and a second resistor including a first node and a second node, where the first node of the second resistor may be directly connected to the input node of the second clamping switch, the second node of the second resistor directly connected to the second source node of the bidirectional switch.

Still further, the second apparatus may further include: a first clamp circuit such as a first diode clamp circuit including at least one unidirectional clamp element such as one or more diode circuit components, where the first clamp circuit may be connected between the first source node and the input node of the first clamping switch; and a second claim circuit such as a second diode clamp circuit including at least one unidirectional clamp element such as one or more diode circuit components, where the second clamp circuit may be connected between the second source node and the input node of the second clamping switch.

It is further noted that a combination of the bidirectional switch and the first clamp circuitry may be integrally fabricated in a single semiconductor chip component. Alternatively, the second apparatus including the clamp circuitry may be fabricated in a first semiconductor chip component while the bidirectional switch (or unidirectional switch as the case may be) is fabricated in the second semiconductor chip component.

The ordering of the steps above has been added for clarity sake. Note that any of the processing operations as discussed herein can be performed in any suitable order.

Other examples of the present disclosure include software programs and/or respective hardware to perform any of the method example steps and operations summarized above and disclosed in detail below.

It is to be understood that the system, method, apparatus, instructions on computer readable storage media, etc., as discussed herein also can be implemented strictly as a software program, firmware, as a hybrid of software, hardware and/or firmware, or as hardware alone such as within a processor (hardware or software), or within an operating system or a within a software application.

As discussed herein, techniques herein are well suited for use in the field of implementing protection circuitry associated with switches. However, it should be noted that examples herein are not limited to use in such applications and that the techniques discussed herein are well suited for other applications as well.

Additionally, note that although each of the different features, techniques, configurations, etc., herein may be discussed in different places of this disclosure, it is intended, where suitable, that each of the concepts can optionally be executed independently of each other or in combination with each other. Accordingly, the one or more present inventions as described herein can be implemented and viewed in many different ways.

Also, note that this preliminary discussion of examples herein (BRIEF DESCRIPTION OF EXAMPLES) purposefully does not specify every example and/or incrementally novel aspect of the present disclosure or claimed invention(s). Instead, this brief description only presents general examples and corresponding points of novelty over conventional techniques. For additional details and/or possible perspectives (permutations) of the invention(s), the reader is directed to the Detailed Description section (which is a summary of examples) and corresponding figures of the present disclosure as further discussed below.

### BRIEF DESCRIPTION OF THE DRAWINGS

FIG. 1 is an example diagram illustrating a bidirectional switch according to the prior art.

FIG. 2 is an example diagram illustrating undesirable turn on of the bidirectional switch in FIG. 1 during exposure to a transient condition as discussed herein.

FIG. 3 is an example diagram illustrating gate clamping and control in a switch as discussed herein.

FIG. 4 is an example detailed circuit diagram illustrating multiple circuit components supporting gate voltage clamping in a switch as discussed herein.

FIG. 5 is an example diagram illustrating gate voltage clamping in a bidirectional switch as discussed herein.

FIG. 6 is an example detailed circuit diagram illustrating multiple circuit components supporting gate voltage clamping in a bidirectional switch as discussed herein.

FIG. 7 is an example diagram illustrating a comparison of circuit operation including excluding gate voltage clamping as discussed herein.

FIG. 8 is an example diagram illustrating operation of the bidirectional switch and corresponding gate voltage clamping circuit and application of a so-called double pulse test as discussed herein.

FIG. 9 is an example diagram illustrating implementation of multiple diodes in the clamp circuit to increase a maximum negative gate voltage without affecting normal operation of a switch during non-transient conditions as discussed herein.

FIG. 10 is an example diagram illustrating increased maximum negative gate voltage capability via the addition of diodes as shown in FIG. 9 as discussed herein.

FIG. 11 is an example method of providing gate voltage clamping capability in a bidirectional switch as discussed herein.

The foregoing and other objects, features, and advantages of the invention will be apparent from the following more particular description of preferred examples herein, as illustrated in the accompanying drawings in which like reference characters refer to the same parts throughout the different views. The drawings are not necessarily to scale, with emphasis instead being placed upon illustrating the examples, principles, concepts, etc.

### DETAILED DESCRIPTION

As further discussed herein, an apparatus (such as circuitry, hardware, etc.) can be configured to include: a bidirectional switch and first clamp circuitry. The bidirectional switch may include a first terminal such as a first gate and a second terminal such as a second gate to receive switch control input. The switch control input such as one or more signals applied to the first gate and the second gate may control (such as prevent, reduce, etc.) flow of current through the bidirectional switch between a third terminal such as a first source node of the bidirectional switch and a fourth terminal such as a second source node of the bidirectional switch or vice versa.

The protection circuitry such as first clamp circuitry as discussed herein can be implemented with respect to a unidirectional switch as well.

In one example, the switch as discussed herein is a gallium nitride field effect transistor (a.k.a., GaN FET), although the switch can be fabricated from any suitable technology. In one example, the field effect transistor as discussed herein is a so-called HEMT device (such as High-Electron-Mobility Transistor) such as a GIT (Gate Injection Transistor) device. Implementation of the first clamp circuitry and/or the second clamp circuitry associated with the main switch prevents undesirable activation of the switch during conditions in which the switch is exposed to transient voltage conditions.

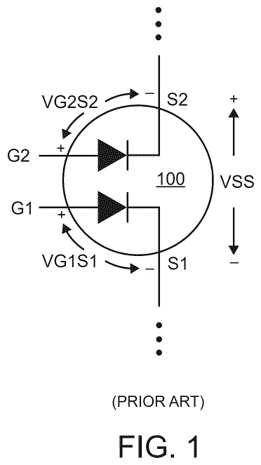

Now, more specifically, FIG. 1 is an example diagram illustrating a bidirectional switch according to the prior art.

In this example, the bidirectional switch 100 (such as a GIT GaN BDS) includes a first gate node G1 and corresponding first source node S1. The bidirectional switch further includes a second gate node G2 and corresponding second source node S2. In other words, in one example, the bidirectional switch 100 as discussed herein may be implemented as a so-called HEMT device (such as High-Electron-Mobility Transistor) such as a GIT (Gate Injection Transistor) device.

As shown, the voltage VG1S1 between the first gate node G1 and the first source node S1 controls flow of current through the bidirectional switch 100 between the source node S2 and the source node S1.

In a similar manner, the voltage VG2S2 between the first gate node G2 and the first source node S2 controls flow of current through the bidirectional switch 100 between the source node S1 and the source node S2.

When the bidirectional switch 100 is in the ON-state, such as when a respective gate-to-source voltage is greater than a threshold level, there is a low impedance path (resistive path) between the first source node S1 and the second source node S2, and vice versa.

Note that implementation of the bidirectional switch 100 in certain circumstances may expose the bidirectional switch 100 to a transient high voltage condition across the source nodes of the bidirectional switch 100.

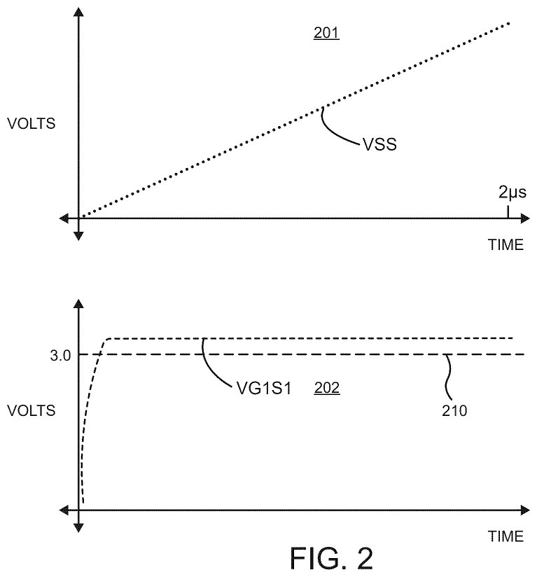

For example, exposure of the bidirectional switch to a transient high voltage condition (also known as a surge voltage event) may result in the voltage VSS between the second source node S2 and the first source node S1 to ramp over time. As shown in FIG. 2, this ramp condition may result in an increase of the gate-to-source voltage VG1S1 to increase above a threshold level, causing the undesirable condition that the bidirectional switch 100 is activated to an ON-state such as low resistive path between the source node S1 and the source node S2.

FIG. 2 is an example diagram illustrating turn on of a bidirectional switch during exposure to a transient condition as discussed herein.

In this example, the graph 201 illustrates results of the bidirectional switch 100 being exposed to a transient voltage condition, causing the ramping of the magnitude of the voltage VSS as shown.

The graph 202 illustrates how the ramping of the voltage VSS over time causes the gate-to-source voltage VG1S1 to increase above the threshold level 210 of around 3 volts DC. The increase of the gate source voltage VG1S1 above the threshold level 210 causes undesirable activation of the bidirectional switch 100 to an ON-state during the transient condition associated with voltage VSS. Below the threshold level 210, the switch 100 is off.

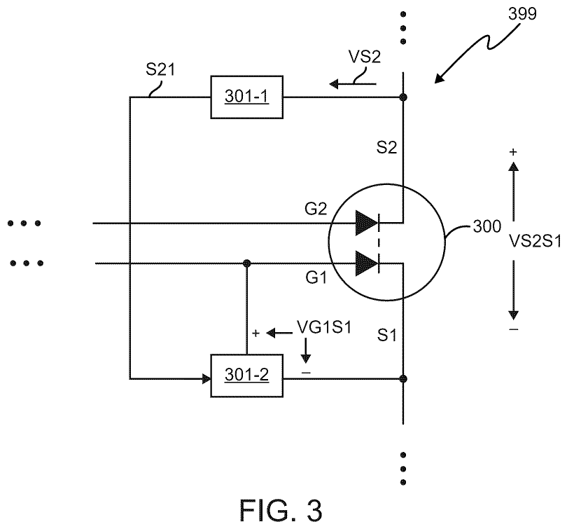

FIG. 3 is an example diagram illustrating gate clamping in a bidirectional switch as discussed herein.

In this example, the circuitry 399 includes control circuitry. Via implementation of the control circuitry 301 (such as combination of capacitor component 301-1, clamp circuitry 301-2, etc.), the switch 300 (such as a bidirectional switch, unidirectional switch, etc.) is prevented from undesirable activation during a condition in which the switch 300 (and corresponding source terminal S1 and/or source terminal S2) is exposed to a transient voltage condition such as the ramping of voltage VS2S1 in a similar manner as discussed in FIG. 2.

As further shown, the capacitor component 301-1 (such as a capacitive component or other suitable entity) receives input such as a voltage VS2 from the node of the capacitor component 301-1 directly connected to the second source terminal S2.

The magnitude of the voltage VS2 varies based upon the transient voltage condition as previously discussed. Based on a change in the magnitude of the voltage VS2, the capacitor component 301-1 produces the signal S21 (such as including energy E1, charge, etc.) supplied to the clamp circuitry 301-2. In other words, the capacitor component 301-1 conveys the AC portion of the voltage VS2 as signal S21 from the source terminal S2 to the clamp circuitry 301-2.

In one example, the signal S21 controls a magnitude of a resistance of the circuit component 301-2 between the first gate terminal G1 and the first source terminal S1. More specifically, the clamp circuitry 301-2 such as a switch or other suitable entity can be configured to reduce a magnitude of the gate-to-source voltage VG1S1 between the gate terminal G1 and the source terminal S1 of the switch 300 via reducing of the magnitude of such resistance associated with the clamp circuitry 301-2. In other words, the signal S21 ensures that the gate-to-source voltage VG1S1 is below a turn on threshold level during the transient condition such as ramping of the voltage VS2S1 in a manner as shown by voltage VSS in graph 201 of FIG. 2.

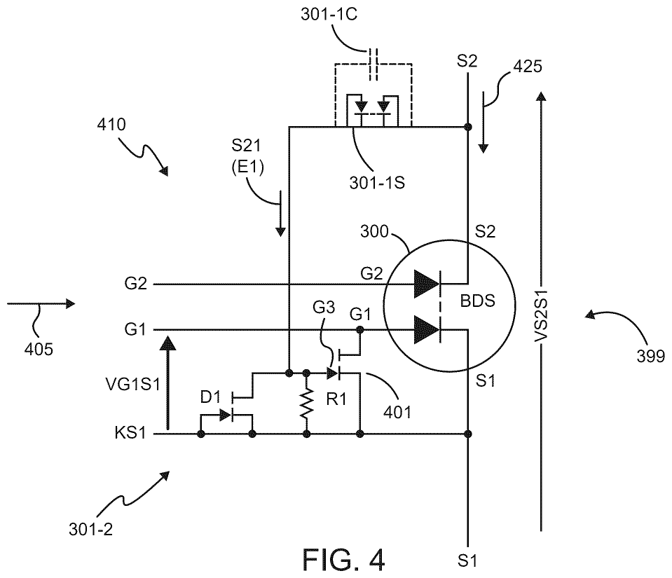

A more specific example of the control circuitry 301 is shown and discussed in FIG. 4.

FIG. 4 is an example detailed circuit diagram illustrating multiple circuit components supporting gate clamping in a switch as discussed herein.

In this more detailed example of the circuitry 399, the capacitor component 301-1 can be implemented as a respective discrete capacitor 301-1C or a switch 301-1S or other suitable entity.

The clamping circuit 301-2 can be configured to include switch D1 (controlling the reverse clamp voltage via one or more diodes), resistor R1, and switch 401.

In one example, the switch 300, switch 301-1S, switch D1, and switch 401 are all fabricated from a same type of field effect transistor fabrication technology. Alternatively, the different components of the circuitry 399 can be fabricated via use of different fabrication technologies. In one example, the switch 300 is fabricated in accordance GaN (Gallium Nitride) technology.

Thus, as shown in FIG. 4, the circuitry 410 includes a bidirectional switch 300 (such as a bidirectional field effect transistor or other suitable entity) and first control circuitry 301 (capacitor component 301-1 and clamping circuit 301-2). The bidirectional switch 300 may include a first gate terminal G1 and a second gate terminal G2 to receive control input 405 (one or more signals). The control input 405 controls flow of current 425 through the bidirectional switch 300 between the source terminal S2 and the source terminal S1 of the bidirectional switch 300.

The first control circuitry 301 (such as a combination of capacitor component 301-1 and clamping circuitry 301-2) may be directly coupled between the second source terminal S2 and the first gate terminal G1, where a combination the first capacitor component 301-1 and the clamping circuitry 301-2 collectively controls a voltage VG1 at the first gate terminal G1 with respect to the voltage VS1 of the first source terminal S1.

Note again that the combination of the bidirectional switch (300) and the first control circuitry 301 or any portion thereof may be integrally fabricated in a single semiconductor chip component. Alternatively, the first control circuitry 301 (such as capacitor component 301-1 and clamping circuitry 301-2) can be implemented in a first semiconductor chip component while the bidirectional switch 300 is implemented in a second semiconductor chip component separate from the first semiconductor chip component.

Further in this example, the note again that the first control circuitry 301 as discussed herein may include a first capacitor (301-1C) configured to provide first capacitive coupling of first energy E1 (charge, voltage, etc.) conveyed in signal S21 from the second source terminal S2, where the first energy controls a magnitude of the voltage at the first gate terminal G1 with respect to a voltage at the first source terminal S1. In other words, when the signal S21 supplies sufficient voltage above a threshold level, switch 401 is activated to clamp the gate-to-source voltage between the gate G1 and the source S1 to a sufficiently low voltage such that the magnitude of current 425 is substantially reduced or prevented altogether. Thus, occurrence of the transient or surge condition associated with the voltage at terminal S2 causes the switch 401 to be in the ON-state, which prevents (a.k.a., substantially reduces a magnitude of) the flow of current 425 through the switch 300. At the time of the surge (transient voltage condition at source terminal S2), either or both of the gate terminal G1 and the gate terminal G2 may not be driven with a control signal, but may be floating.

Thus, the first control circuitry 301 as discussed herein may include a first circuit path, where the first circuit path extends between the first gate terminal G1 and the second source terminal S2, and where the first circuit path includes a first capacitor component 301-1 (such as capacitor 301-1C or switch 301-1S which acts as a capacitor) and a switch 401 in series.

In a further example, the bidirectional switch (300) may be a first bidirectional switch; the first capacitor component (such as switch 301-1S) associated with the control circuitry 301 may be implemented as a second bidirectional switch in the circuitry 399.

Yet further, as previously discussed, the switch 401 can be configured to include a first output node directly connected to the first gate terminal G1 and a second output node directly connected to the first source terminal S1. The capacitor component 301-1 supplies a control voltage (signal S21) to an input node (gate node) of the switch 401, where the control voltage is configured to control a resistance provided by the 401 between the first gate terminal G1 and the first source terminal S1. In one example, conveyance of the energy E1 in the signal S21 activates the switch 401, causing a low impedance (resistance) path to be created between the first gate terminal G1 and the first source terminal S1, therefore shutting off the switch 300 and preventing flow of the current 425 through the switch 300 because a magnitude of the gate-to-source voltage between the first gate terminal G1 and the first source terminal S1 is below a switch turn on voltage threshold level.

Further, as previously discussed, note again that the switch 401 can be configured to operate in a normally OFF-state prior to reception of the control voltage (signal S21 or energy E1) conveyed via the first capacitor component 301-1 to the gate G3 of the switch 401. Alternatively, as previously discussed, the switch 401 operates in an ON-state during a condition in which the control voltage (such as signal S21) is above a threshold level with respect to the first source terminal S1. The resistor R1 eventually dissipates the voltage associated with the signal S21 (and energy E1) over time to 0, resulting in shutting off the respective switch 401. In this latter case, the clamping circuitry 301 no longer controls operation of the respective switch 300 in the control signals 405 control operation of the respective switch 300.

Accordingly, examples as discussed herein include a method of controlling a switch 300 including a first gate terminal G1 and a second gate terminal G2, where the first gate terminal G1 and the second gate terminal G2 are operative to control flow of current 425 between a first source terminal S1 and a second source terminal S2 of the switch 300. The method may include: receiving a voltage (signal S21 such as a voltage or energy E1) generated or supplied from the second source terminal S2 of the bidirectional switch 300; and based on the second voltage VS2 and/or corresponding signal S21 received from the change in voltage at the second source terminal S2, the clamp circuitry 301-2 such as first clamping switch 401 controls a first resistance provided by the clamping switch 401 between the first gate terminal G1 and the first source terminal S1.

As previously discussed, control of the first resistance of the first clamping switch 401 may include: via a capacitive circuit component such as capacitor component 301-1, conveying energy E1 via signal S21 from the second source terminal S2 to the gate node G3 of the first clamping switch 401. The conveyance of the energy E1 (caused by AC coupling between the source node S2 to the gate node G3) results in activation of the switch 401 to an ON-state, which produces a low impedance path (first resistance) between the first gate terminal G1 and the first source terminal S1 of the switch 300.

It is further noted that the clamping circuitry 301-2 includes the resistor R1 connected between the gate node G3 of the switch 401 and a source node of the switch 401 (and the source node S1 of the switch 300). The resistor R1 serves to discharge the energy E1 provided by the capacitive coupling associated with capacitor component 301-1 (such as capacitor 301-1C or switch 301-S) such that the switch 401 is transitioned or maintained in an OFF-state during non-transient conditions with respect to the first source terminal S1 and the second source terminal S2.

During non-transient conditions, any suitable resource produces the control input 405 applied to the first gate G1 and the second gate G2 to control operation and flow of a respective current 425 through the switch 300.

It is further noted that the clamping circuitry 301-2 can be configured to include the switch D1 and diode. Implementation of the switch D1 as shown provides a diode clamp between the node G3 of the switch 401 and the first source terminal S1.

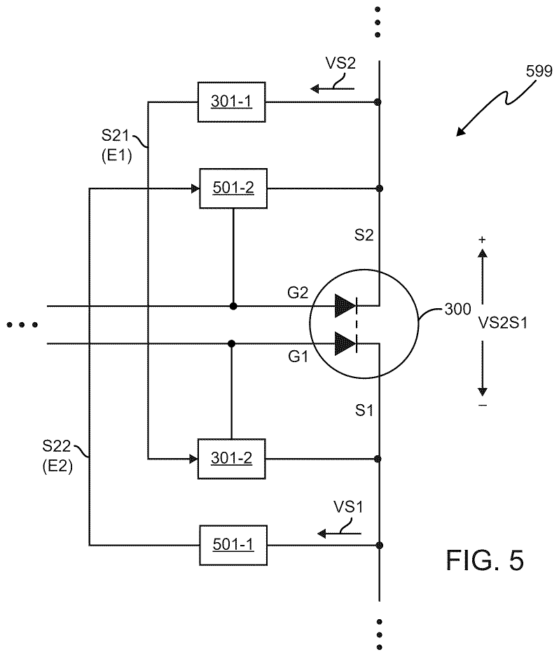

FIG. 5 is an example diagram illustrating dual gate clamping in a bidirectional switch as discussed herein.

In this example, the circuitry 599 includes switch 300 as well as the first control circuitry 301 (capacitor component 301-1 and clamping circuitry 301-2) as previously discussed. The circuitry 599 further includes second control circuitry 501 (such as combination of capacitor component 501-1 and clamping circuitry 501-2) as discussed below. This implementation (circuitry 599) supports dual gate clamping.

More specifically, via implementation of the control circuitry 501 (such as capacitor component 501-1, clamp circuitry 501-2, etc.), the switch 300 (such as a bidirectional switch, etc.) is prevented from undesirable activation during a condition in which the switch 300 and corresponding source terminal S1 and/or source terminal S2 are exposed to a transient voltage condition such as the transient voltage condition as previously discussed with respect to FIG. 2.

As further shown, the capacitor component 501-1 (such as a capacitive component) receives input such as a voltage VS1 from the source terminal S1. Based on a magnitude of the voltage VS1 such as experiencing a transient voltage condition, the capacitor component 501-1 produces the signal S22 (such as including energy E2 or charge) supplied to the clamp circuitry 501-2.

In one example, the signal S22 and corresponding energy E2 controls a magnitude of a resistance in the circuitry 501-2 between the second gate terminal G2 and the second source terminal S2. More specifically, the clamp circuitry 501-2 can be configured to reduce a magnitude of the gate-to-source voltage VG2S2 between the second gate terminal G2 and the second source terminal S2 via reducing of the magnitude of the resistive path in the clamping circuitry 501-2 between the second gate terminal G2 and the second source terminal S2. In such an instance, the signal S22 and corresponding energy E2 or charge generated based upon a transient change in the voltage VS2 ensures that the gate-to-source voltage VG2S2 is below a turn on threshold level during the transient condition such as when the voltage VS2S1 ramps in a manner or is exposed to a transient condition change in voltage as shown by voltage VSS in graph 201 of FIG. 2.

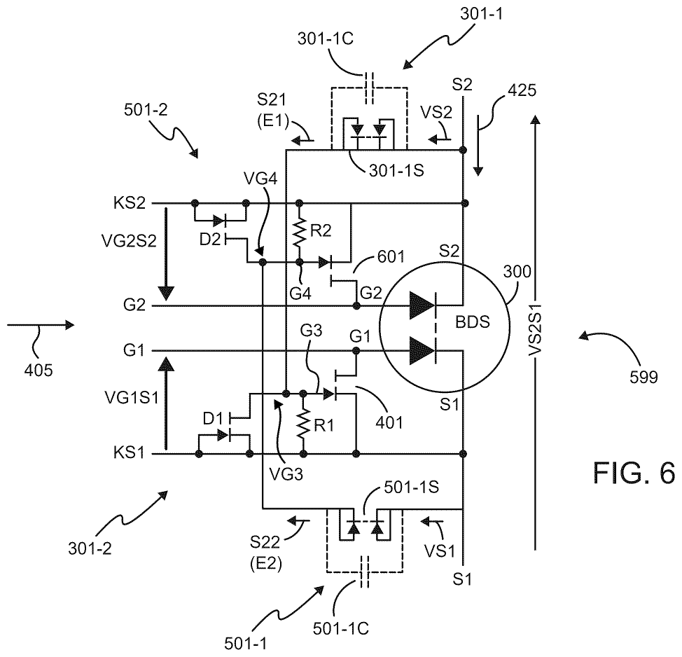

A more specific example of the control circuitry 501 is shown and discussed in FIG. 6.

FIG. 6 is an example detailed circuit diagram illustrating multiple circuit complements supporting gate clamping in a bidirectional switch as discussed herein.

In this example of the circuitry 599, the capacitor component 501-1 can be implemented as a respective discrete capacitor 501-1C or a switch 501-1S or other suitable entity.

The clamping circuit 501-2 can be configured to include switch D2 (controlling the reverse clamp voltage via one or more diodes), resistor R2, and switch 601.

In one example, the switch 300 (a.k.a., main switch), switch 501-1S, switch D1, and switch 601 are fabricated from a same type of field effect transistor fabrication technology.

Thus, as shown in FIG. 6, in addition to including the clamping circuitry 301 as previously discussed, the circuitry 599 includes a bidirectional switch 300 (such as a bidirectional field effect transistor or other suitable entity) and control circuitry 501. The bidirectional switch 300 may include a first gate terminal G1 and a second gate terminal G2 to receive control input 405 (one or more control signals). The control input 405 controls flow of current 425 through the bidirectional switch 300 between the source terminal S2 and the source terminal S1 of the bidirectional switch 300. In one example, a drain node D1 associated with the gate terminal G1 and source terminal S1 is directly connected in the bidirectional switch 300 to a drain node D2 associated with the gate terminal G2 in the source terminal S2. Accordingly, the bidirectional switch 300 may represent two field effect transistors connected in series via connection of corresponding drain node D1 and drain node D2.

The control circuitry 501 (such as a combination of capacitor component 501-1 and clamping circuitry 501-2) may be directly coupled between the first source terminal S1 and the second gate terminal G2, where a combination the capacitor component 501-1 and the clamping circuitry 501-2 collectively controls a voltage VG2 at the gate terminal G2 with respect to the source terminal S2. In one embodiment, at the time of the surge (transient voltage condition at source terminal S2 or source terminal S1), either or both of the gate terminal G1 and the gate terminal G2 may not be driven with a control signal, but may be floating. The clamping circuitry as discussed herein provides turn-of protection in both directions in such an instance as well as potentially when the gate terminals are driven.

Note that the combination of the bidirectional switch (300) and the first control circuitry 301 and second control circuitry 501 may be integrally fabricated in a single semiconductor chip component.

Alternatively, the first control circuitry 301 (such as capacitor component 301-1 and clamping circuitry 301-2) and the second control circuitry 502 (such as capacitor component 501-1 and the clamping circuitry 501-2) can be implemented in a first semiconductor chip component while the bidirectional switch 300 is implemented in a second semiconductor chip component separate from the first semiconductor chip component.

Further in this example, the note again that the control circuitry 501 as discussed herein may include a first capacitor (501-1C) configured to provide first capacitive coupling of first energy E2 conveyed in signal S22 from the source terminal S1, where the energy E2 controls a magnitude of the voltage at the gate terminal G2 with respect to a voltage at the source terminal S2.

Thus, the first control circuitry 501 as discussed herein may include a second circuit path, where the second circuit path extends between the gate terminal G2 and the source terminal S1, and where the second circuit path includes a first capacitor component 501-1 (such as capacitor 501-1C or switch 501-1S which acts as a capacitor) and a switch 601 in series.

In a further example, the bidirectional switch (300) may be a first bidirectional switch; the capacitor component (such as switch 501-1S) associated with the control circuitry 501 may be implemented as a second bidirectional switch in the circuitry 599.

Yet further, as previously discussed, the switch 601 can be configured to include a first output node directly connected to the gate terminal G2 and a second output node directly connected to the source terminal S2. The capacitor component 501-1 supplies a control voltage (signal S22) to an input node (gate node G4) of the switch 601, where the control voltage (S22) is configured to control a resistance provided by the switch 601 between the gate terminal G2 and the source terminal S2.

In one example, conveyance of the energy E2 in the signal S22 activates the switch 601, causing a low impedance (resistance) path to be created between the gate terminal G2 and the source terminal S2, therefore shutting off the switch 300 and preventing flow of the negative current 425 through the switch 300 because a magnitude of the gate-to-source voltage between the gate terminal G2 and the source terminal S2 is below a voltage threshold level.

Further, as previously discussed, note again that the switch 601 can be configured to operate in a normally OFF-state prior to reception of the control voltage (signal S22 or energy E2) conveyed via the first capacitor component 501-1 to the gate G4 of the switch 601. Alternatively, as previously discussed, the switch 601 operates in an ON-state during a condition in which the control voltage (such as signal S22) is above a threshold level with respect to the source terminal S2. The resistor R2 eventually dissipates the voltage (and energy E2) supplied by the signal S22 over time to 0, resulting in shutting off the respective switch 601. In this latter case, the clamping circuitry 501-2 and corresponding switch 601 no longer controls operation of the respective switch 300. Instead, the control signals 405 control operation of the respective gate terminals G1 and G2 and corresponding switch 300 during non-transient conditions.

Accordingly, the bi-directional gate clamp circuitry as shown in FIG. 6 can be configured to include two circuits, each to couple the gate clamp circuit to the opposite source through a bi-directional blocking switch (Bx). The gate clamp circuitry as discussed herein may include a normally OFF pulldown switch (401) between the gate G1 and source S1, a resistor (R1) to discharge the gate and source and a gate protection diode (D1) to protect the gate G1 in the reverse direction. The gate G3 of the transistor 401 may be directly coupled to the opposite source through the capacitive component 301-1. The aim is to charge the gate of transistor 401 during the surge event, therefore the capacitor component 301-1 simply acts as a capacitor and may be replaced with a high-voltage capacitor (301-1C) if doing so is more space efficient. A bi-directional blocking device may be required here to protect the switches 401 and 601 from the higher voltages of the resources.

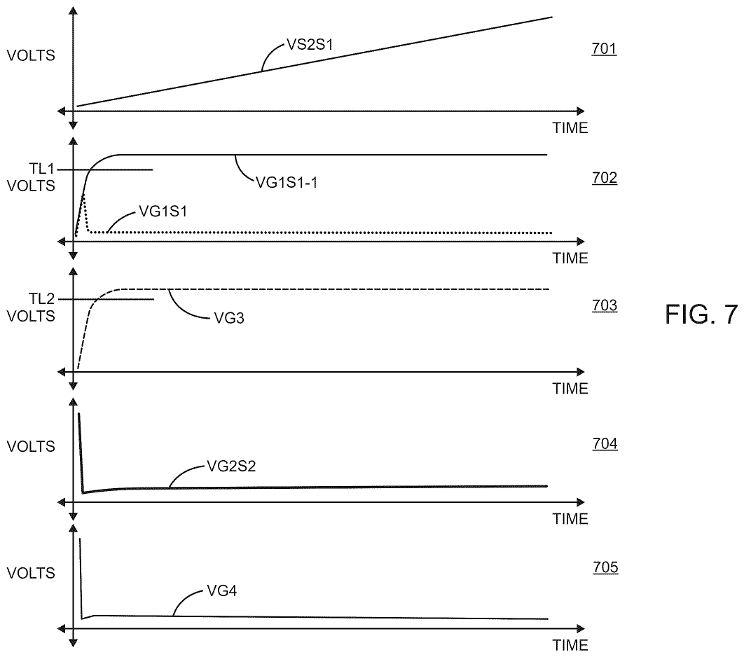

FIG. 7 is an example diagram illustrating a comparison of circuit operation including excluding gate clamping as discussed herein.

In general, the graphs in FIG. 7 illustrate simulated results of the bi-directional gate clamp circuitry (301, 501) based on exposure to an 800 volts ramp voltage starting from zero volts, where the ramp voltage is between the source terminal S2 and the source terminal S1, within a timeframe of two micro seconds or other suitable amount.

This example illustrates preventing turn on of the switch 300 between the source terminal S2 and the source terminal S1 based on exposure of the switch 300 and corresponding source terminal S2 and/or source terminal S1 exposed to a transient condition (ramp shown in graph 701).

More specifically, graph 701 illustrates a magnitude of the voltage VS2S1 between the second source terminal S2 and the first source terminal S1 over time during exposure of the switch 300 to a transient condition such as caused by electrostatic discharge, lightning, or any other environmental condition.

Graph 702 illustrates a magnitude of the gate source voltage VG1S1-1 (between the first gate terminal G1 and the first source terminal S1) without implementation of the control circuitry 301 (a.k.a., switch turn on prevention circuitry) as discussed herein.

It is noted that implementation of the control circuitry 301 prevents undesirable turn on of the switch 300 during the transient condition. Graph 702 also illustrates a magnitude of the gate-to-source voltage VG1S1 (between the first gate terminal G1 and the first source terminal S1) based on implementation of the control circuitry 301 (a.k.a., switch turn on prevention circuitry) as discussed herein. As previously discussed, clamping of the gate-to-source voltage between the first gate terminal G1 and the first source terminal S1 below a turn on threshold level TL1 associated with the switch 300 during the transient condition prevents the switch 300 from turning on.

Graph 703 illustrates a magnitude of the voltage VG3 at the gate node G3 of the switch 401 in response to receiving the signal S21 and corresponding energy E1 as previously discussed. Receipt of the energy E1 at the gate node G3 causes the switch 401 to be activated to an ON-state based on the magnitude of the voltage VG3 being above the turn on threshold level TL2, further resulting in a low impedance path between the first gate terminal G1 and the first source terminal S1 of the switch 300.

The VG2S2 and VG4 waveforms are also shown in graphs similar 704 and 705, showing the reverse gate being off during this condition to enhance the voltage blocking capability of the BDS.

Graph 704 illustrates a magnitude of the gate-to-source voltage VG2S2 between the second gate terminal G2 and the second source terminal S2 over time.

Graph 705 illustrates a magnitude of the voltage VG4 of the gate node of the switch 601 over time.

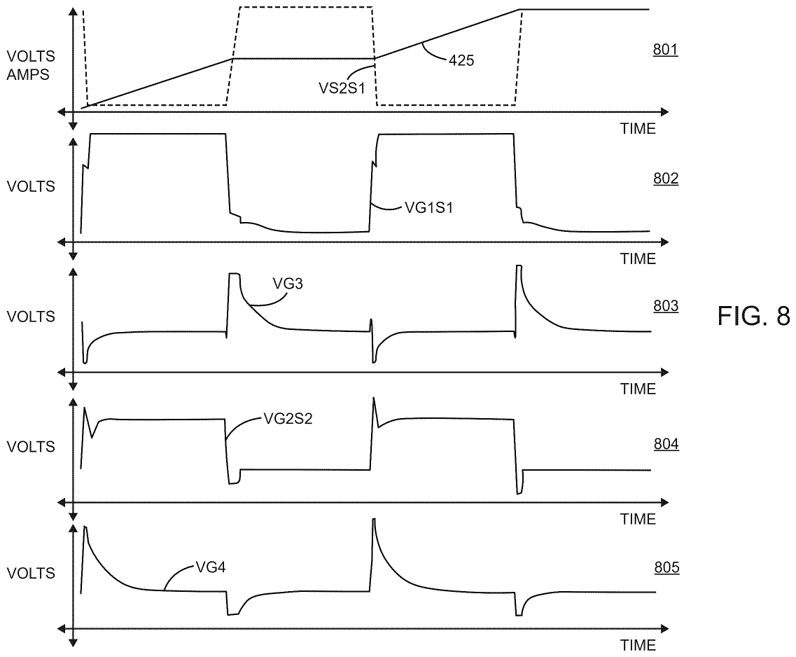

FIG. 8 is an example diagram illustrating operation of the bidirectional switch and corresponding gate clamping circuit during a so-called double pulse test as discussed herein.

This example illustrates use of the switch 300 during a non-transient condition, where the switch 300 is controlled via control signals 405 resulting in the flow of current 425 through the switch 300.

One desirable feature of implementing the control circuits such as clamp circuitry is to only implement clamping of the gate-to-source voltages during surge events (transient conditions). During non-transient events, it is desirable that the clamping between a respective gate the respective source does not occur during normal operating conditions.

FIG. 8 and corresponding graphs illustrate operation of the circuitry in FIG. 6 under a so-called common double pulse test simulation from 400V DC. During an ON-state of the switch 300, the VG1S1 is correct and the gate voltage VG3 is basically at zero volts with some negative voltage during the turn on, which ensures the pulldown does not improperly pulldown the voltage VG1S1. During the turn off event of the switch 300, the voltage VG3 is momentarily high to turn on the switch 401, which temporarily reduces a magnitude of the voltage VG1S1 as previously discussed.

It is further noted that the voltage VG2S2 also operates as required during normal operating conditions. However, on this gate terminal G2 of the switch 300, the turn on event helps the VG2S2 turn on quickly due to the dv/dt discharge, the same transition actually turns on the switch 601 as well. Since this same operating is turning on the switch 300 via application of a control signal to the gate terminal G2, the effect is not a problem. The voltage VG4 at the gate node G4 quickly discharges to zero to avoid any false pulldown down issue of the second gate terminal G2.

Thus, graph 801 illustrates a magnitude of the voltage VS2S1 between the second source terminal S2 and the first source terminal S1 over time based on application of control signals 405, controlling turn on and turnoff of the switch 300. Graph 801 further illustrates a magnitude of the current 425 conveyed through the switch 300.

Graph 802 illustrates a magnitude of the gate-to-source voltage VG1S1 (between the first gate terminal G1 and the first source terminal S1) via implementation of the control circuitry 301 (a.k.a., switch turn on prevention circuitry) as discussed herein.

Graph 803 illustrates a magnitude of the voltage VG3 at the gate node G3 of the switch 401 over time.

Graph 804 illustrates a magnitude of the gate-to-source voltage VG2S2 between the second gate terminal G2 and the second source terminal S2 over time.

Graph 805 illustrates a magnitude of the voltage VG4 of the gate node of the switch 601 over time.

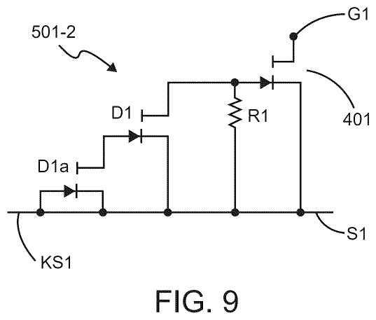

FIG. 9 is an example diagram illustrating implementation of multiple diodes in the clamp circuit to increase a maximum negative gate voltage without affecting normal operation during non-transient conditions as discussed herein.

One limitation associated with the clamp circuitry as discussed herein is that it potentially limits the maximum reverse gate voltage that can be applied to the gate since the component D1 and transistor 401 forms a reverse clamp diode. This can be seen in VG1S1, where the reverse gate voltage is limited to around −1.5V.

In one example, in order to increase this capability and voltage, techniques herein include adding one or more diodes to the gate of transistor D1 as shown in FIG. 9. In this example, the transistor D1a is added to increase the maximum reverse gate voltage. Note that additional transistors can be added in a similar manner to further increase a magnitude of this voltage.

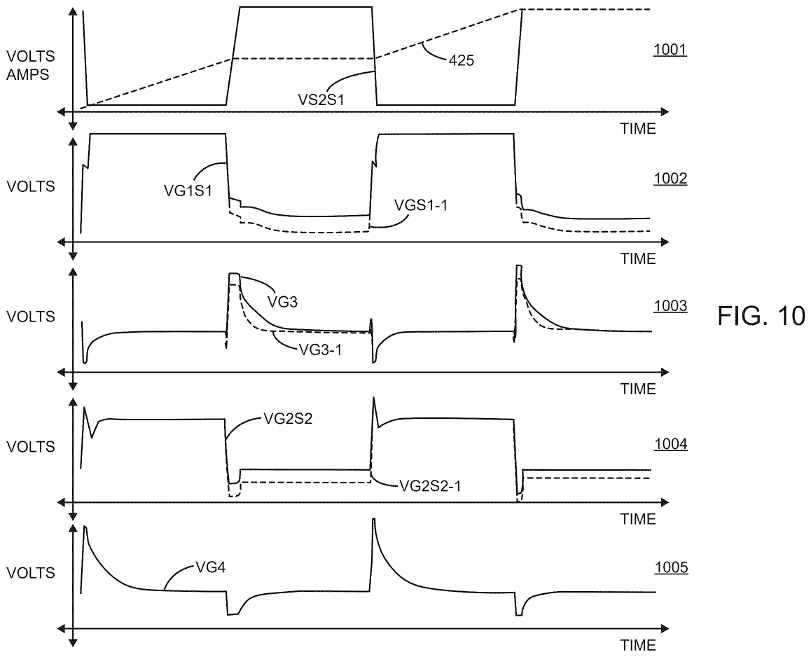

Note that a simulated example of this modification in FIG. 9 is shown in FIG. 10, where the VG1S1 can be seen to have a high negative gate voltage without affecting the normal operation of the circuit.

FIG. 10 is an example diagram illustrating increased maximum negative gate voltage capability via the addition of diodes as shown in FIG. 9 as discussed herein.

As previously discussed, a magnitude of the current 425 (a.k.a., IL OR iLOAD) through the respective switch 300 may vary over time based on received control signals 405. Implementation of the transistor configuration in FIG. 9 results in an increase in the maximum negative gate voltage.

Graph 1001 illustrates a magnitude of the voltage VS2S1 between the second source terminal S2 and the first source terminal S1 over time based on application of control signals 405, controlling turn on and turnoff of the switch 300. Graph 1001 further illustrates a magnitude of the current 425 conveyed through the switch 300.

Graph 1002 illustrates a magnitude of the gate-to-source voltage VG1S1 (between the first gate terminal G1 and the first source terminal S1) via implementation of the control circuitry 301 (a.k.a., switch turn on prevention circuitry) as discussed herein. Graph 802 also illustrates a magnitude of the gate-to-source voltage VG1S1-1 (between the first gate terminal G1 and the first source terminal S1) via implementation of the clamp circuitry 501-2 as shown in FIG. 9.

Graph 1003 illustrates a magnitude of the voltage VG3 at the gate node G3 of the switch 401 over time. Graph 1003 also illustrates a magnitude of the voltage VG3-1 at the gate node G3 of the switch 401 over time via the implementation of the clamp circuitry 501-2 as shown in FIG. 9.

Graph 1004 illustrates a magnitude of the gate-to-source voltage VG2S2 between the second gate terminal G2 and the second source terminal S2 over time. Graph 1004 also illustrates a magnitude of the gate-to-source voltage VG2S2-1 between the second gate terminal G2 and the second source terminal S2 over time via the implementation of the clamp and circuitry 501-2 as shown in FIG. 9.

Graph 1005 illustrates a magnitude of the voltage VG4 of the gate node of the switch 601 over time.

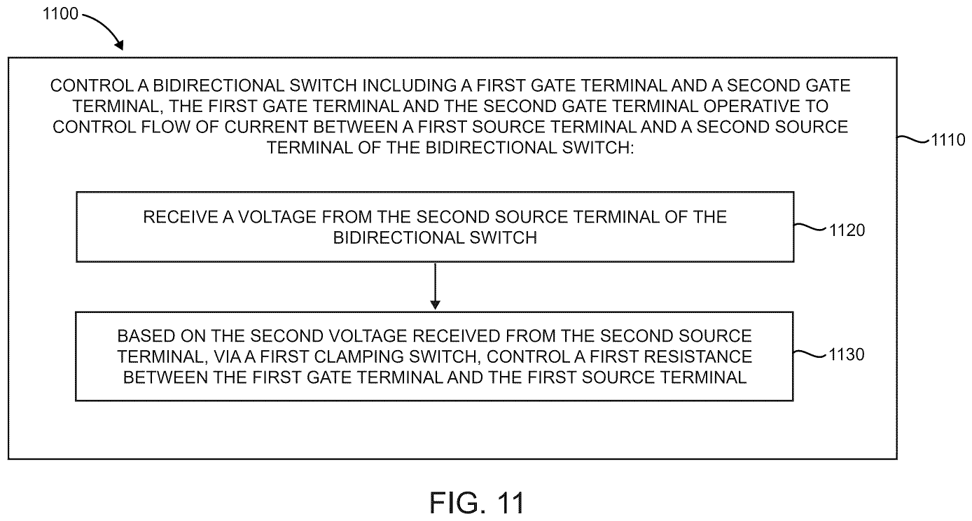

FIG. 11 is an example method of providing gate voltage clamping capability in a bidirectional switch as discussed herein.

In the flowchart 1100 as shown in FIG. 11, in processing operation 1110, the control circuitry 301 controls a switch 300 including a first gate terminal G1 and a second gate terminal G2, where control input to the first gate terminal G1 and the second gate terminal G2 is operative to control flow of current 425 through the switch 300 and corresponding first source terminal S1 and second source terminal S2.

In processing operation 1120, the capacitor component 301-1 of the control circuitry 301 receives or monitors a voltage VS2 from the second source terminal S2 of the switch 300. The capacitor component 301-1 conveys the signal S21 (such as an AC portion of the voltage VS2) and corresponding energy to the clamp circuitry 301-2.

In processing operation 1130, based on the second voltage VS2 and corresponding received signal S21 (energy E1), the clamping switch 401 of the clamping circuitry 301-2 controls a first resistance of the switch 401 between the first gate terminal G1 and the first source terminal S1.

Note again that techniques herein are well suited for use in circuit applications such as those implementing bidirectional switch circuitry and corresponding gate clamp control. However, it should be noted that examples herein are not limited to use in such applications and that the techniques discussed herein are well suited for other applications as well.

Based on the description set forth herein, numerous specific details have been set forth to provide a thorough understanding of claimed subject matter. However, it will be understood by those skilled in the art that claimed subject matter may be practiced without these specific details. In other instances, methods, apparatuses, systems, etc., that would be known by one of ordinary skill have not been described in detail so as not to obscure claimed subject matter. Some portions of the detailed description have been presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm as described herein, and generally, is considered to be a self-consistent sequence of operations or similar processing leading to a desired result. In this context, operations or processing involve physical manipulation of physical quantities. Typically, although not necessarily, such quantities may take the form of electrical or magnetic signals capable of being stored, transferred, combined, compared or otherwise manipulated. It has been convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, as apparent from the following discussion, it is appreciated that throughout this specification discussions utilizing terms such as “processing,” “computing,” “calculating,” “determining” or the like refer to actions or processes of a computing platform, such as a computer or a similar electronic computing device, that manipulates or transforms data represented as physical electronic or magnetic quantities within memories, registers, or other information storage devices, transmission devices, or display devices of the computing platform.

While this invention has been particularly shown and described with references to preferred examples thereof, it will be understood by those skilled in the art that various changes in form and details may be made therein without departing from the spirit and scope of the present application as defined by the appended claims. Such variations are intended to be covered by the scope of this present application. As such, the foregoing description of examples of the present application is not intended to be limiting. Rather, any limitations to the invention are presented in the following claims.

1. An apparatus comprising:
a first clamping switch coupled between a first terminal and a second terminal of a switch, the first clamping switch operative to prevent flow of current through the switch between a third terminal of the switch and the second terminal of the switch; and
wherein the first clamping switch is operative to control a first resistance between the first terminal and the second terminal of the switch based on a voltage at the third terminal.

2. The apparatus as in claim 1 further comprising:
a fourth terminal;
wherein the switch is a bidirectional switch;
wherein the first terminal is a first gate node of the bidirectional switch;
wherein the second terminal is a first source node of the bidirectional switch;
wherein the third terminal is a second source node of the bidirectional switch;
wherein the fourth terminal is a second gate node of the bidirectional switch.

3. The apparatus as in claim 2 further comprising:
a second clamping switch coupled between the second gate node and the second source node, the second clamping switch operative to prevent flow of current through the switch between the first source node and the second source node of the switch; and
wherein the second clamping switch is operative to control a second resistance between the second gate node and the second source node of the switch based on a voltage at the first terminal.

4. The apparatus as in claim 3 further comprising:
a first capacitive circuit component operative to convey first energy supplied from the second source node to an input node of the first clamping switch, the conveyed first energy operative to control a magnitude of the first resistance; and
a second capacitive circuit component operative to convey second energy supplied from the first source node to an input node of the second clamping switch, the conveyed second energy operative to control a magnitude of the second resistance.

5. The apparatus as in claim 4 further comprising:
a first resistor including a first node and a second node, the first node of the first resistor directly connected to the input node of the first clamping switch, the second node of the first resistor directly connected to the first source node; and
a second resistor including a first node and a second node, the first node of the second resistor directly connected to the input node of the second clamping switch, the second node of the second resistor directly connected to the second source node.

6. The apparatus as in claim 5 further comprising:
a first clamp circuit including at least one unidirectional conducting element, the first clamp circuit connected between the first source node and the input node of the first clamping switch; and
a second clamp circuit including at least one unidirectional conducting element, the second clamp circuit connect between the second source node and the input node of the second clamping switch.

7. The apparatus as in claim 1, wherein a combination of the switch and the first clamp circuitry are integrally fabricated in a single monolithic semiconductor chip.

8. An apparatus comprising:
a bidirectional switch including a first gate terminal, a first source terminal, a second gate terminal, and a second source terminal; and
first switch circuitry coupled between the first gate terminal and the first source terminal, the first switch circuitry operative to control a voltage of the first gate terminal based on a magnitude of a voltage at the second source terminal.

9. The apparatus as in claim 8 further comprising:
second switch circuitry coupled between the second gate terminal and the second source terminal, the second switch circuitry operative to control a voltage at the second gate terminal based on a magnitude of a voltage at the first source terminal.

10. The apparatus as in claim 9, wherein a combination of the bidirectional switch, the first switch circuitry, and the second switch circuitry are integrally fabricated in a single monolithic semiconductor chip.

11. The apparatus as in claim 8, wherein the bidirectional switch is a GaN (Gallium Nitrite) bidirectional field effect transistor.

12. The apparatus as in claim 8 further comprising:
a first capacitor component operative to provide first capacitive coupling between the second source node and a control input of the first switch circuitry, the first capacitor component operative to convey first energy from the second source terminal to the first switch circuitry.

13. The apparatus as in claim 12, wherein the first capacitor component is operative to convey the first energy from the second source terminal to the first switch circuitry in response to a transient change in a magnitude of the voltage at the second source terminal; and
wherein the first energy temporarily activates the first switch circuitry to an ON-state.

14. The apparatus as in claim 8, wherein a resistance provided by the first switch circuitry between the first gate terminal and the first source terminal depends on energy conveyed from the second source terminal to the first switch circuitry during a transient change in the magnitude of the voltage at the second terminal.

15. The apparatus as in claim 8 further comprising:
a first circuit path extending between the second source terminal and the first switch circuitry, the first circuit path including a first capacitor component, the first circuit path operative to control an operational state of the first switch circuitry.

16. The apparatus as in claim 15, wherein the bidirectional switch is a first bidirectional switch; and
wherein the first capacitor component is implemented via second switch circuitry, the second switch circuitry being a bidirectional switch.

17. The apparatus as in claim 8, wherein the voltage at the second source terminal is a transient voltage, the apparatus further comprising:
a first circuit path extending between the second source terminal and an input node of the first switch circuitry.

18. The apparatus as in claim 17, wherein a first output node of the first switch circuitry is directly connected to the first source terminal;
wherein a second output node of the first switch circuitry is directly connected to the first source terminal;
wherein the first switch circuitry is configured to operate in a normally OFF-state prior to reception of an input control signal applied to the input node; and
wherein the first switch circuitry is configured to operate in an ON-state during a condition in which the magnitude of the voltage at the second source terminal is above a threshold level.

19. The apparatus as in claim 8, wherein a resistance of the first switch circuitry is controlled based on the magnitude of the voltage at the second source terminal.

20. The apparatus as in claim 19 further comprising:
second switch circuitry connected between the second gate terminal and the second source terminal; and
wherein a resistance of the second switch circuitry between the second gate terminal and the second source terminal is controlled based on a voltage at the first gate terminal of the bidirectional switch.

21-26. (canceled)
